(19) United States
(12) Patent Application Publication
(10) Pub. No.: US 2015/0069618 A1
(43) Pub. Date: Mar. 12, 2015

(54) Method for forming through wafer vias

(71) Applicant: Innovative Micro Technology, Goleta, CA (US)

(72) Inventors: Christopher S. Gudeman, Lompoc, CA (US); Prosenjit Sen, Bangalore (IN)

(73) Assignee: Innovative Micro Technology, Goleta, CA (US)

(21) Appl. No.: 13/987,871

(22) Filed: Sep. 11, 2013

(51) Int. Cl. H01L 21/48; H01L 23/48

(52) U.S. Cl. CPC H01L 21/486; H01L 23/481
USPC 257/774; 438/667; 438/466

(57) ABSTRACT

A method for forming through substrate vias (TSVs) in a non-conducting, glass substrate is disclosed. The method involves patterning a silicon template substrate with a plurality of lands and spaces, bonding a slab or wafer of glass to the template substrate, and melting the glass so that it flows into the spaces formed in the template substrate. The template substrate may then be removed to leave a plurality of TSVs in the glass slab or wafer.

### CROSS REFERENCE TO RELATED APPLICATIONS

Not applicable.

### STATEMENT REGARDING FEDERALLY SPONSORED RESEARCH

Not applicable.

### STATEMENT REGARDING MICROFICHE APPENDIX

Not applicable.

### BACKGROUND

This invention relates to integrated circuit and microelectromechanical systems (MEMS) devices. More particularly, this invention relates to the formation of vias in wafers on which the integrated circuits and MEMS devices may be fabricated.

Microelectromechanical systems (MEMS) are very small moveable structures made on a substrate using lithographic processing techniques, such as those used to manufacture semiconductor devices. MEMS devices may be moveable actuators, sensors, valves, pistons, or switches, for example, with characteristic dimensions of a few microns to hundreds of microns. One example of a MEMS device is a microfabricated cantilevered beam, which may be used to switch electrical signals. Because of its small size and fragile structure, the movable cantilever may be enclosed in a cavity to protect it and to allow its operation in an evacuated environment. Therefore, upon fabrication of the moveable structure on a wafer, (device wafer) the device wafer may be mated with a lid wafer, in which depressions have been formed to allow clearance for the structure and its movement. To maintain the vacuum over the lifetime of the device, a getter material may also be enclosed in the device cavity upon sealing the lid wafer against the device wafer.

In order to control such a microfabricated switch, electrical access must be provided that allows power and signals to be transmitted to and from the switch. Vias are typically formed in at least one of the wafers to provide this access. If the switch is for high frequency signals, it may also be important to design the vias such that their electrical effects on the signals are minimized or at least known and understood.

Accordingly, electrical vias allow electrical access to electronic devices or microelectromechanical systems (MEMS) within a package or in a circuit. In order to continually reduce the cost of such packages and circuits, the packing density of devices within the packages and circuits has been continually increased. In order to support the increase in packing density, the pitch between electrical vias for the devices has also continued to shrink. As a consequence, there is a desire to form vias of increasingly large aspect ratio, that is, the vias are tending to become increasingly long and narrow. Furthermore increased packing density requires that the placement tolerance of the vias be tightly controlled, since increased placement uncertainty requires the center to center separation be increased to avoid inadvertent shorting of adjacent vias.

Long, narrow vias are often created by plating a conductive material into a hole formed in a substrate. A hole may be created in a substrate by a directional material removal process such as reactive ion etching (RIE). A seed layer is then deposited conformally over the etched surface, to provide a conductive layer to attract the plating material from the plating bath.

However, when using this approach, the plating material in the bath has a tendency to be increasingly depleted down the depth of the hole. This will cause the plating rate to be higher at the top and near zero at the bottom, resulting in pinch-off at the top. Since the aperture to the via has become closed, the plating bath no longer circulates and the confined bath within the hole is exhausted of its plating species. Plating into the hole will then cease, and a void is formed beneath the point of closure of the via aperture. Since these problems worsen as the via becomes longer and narrower, this approach becomes increasingly difficult for long, narrow vias. Specialized bath chemistries have been developed that reduce the negative effects cited above, but they can be expensive and are difficult to control.

Another known method for making vias is to use an anisotropic etch to form the holes with sloping sidewalls, and to deposit the conductive material on the sloped walls of the holes. However, this method often results in conductive material having non-uniform thickness, and the heat conduction in the thin deposited layer is relatively poor. The aspect ratio must also remain near 1:2 (width=2×depth), further limiting the density of the vias.

Each of these approaches involves the removal of substrate material in the hole to form the via, and the filling of this hole with a conductive material. The hole may be made by, for example, the methods described above and then filled by electroplating gold or copper. Because of the aforementioned problems with these approaches, such methods generally limit the aspect ratio of the via formed, and are also applicable only to conductive substrates.

Therefore, a need exists for a methodology which can form vias with high aspect ratio, and in a non-conductive substrate such as glass or fused silica.

### SUMMARY

A method is described which can be used to make conductive vias in a non-conductive substrate with large aspect ratios and without etching or removing material.

A feature of this process is that vertical columns are formed on a flat template substrate, and a through substrate via (TSV) wafer of glass is placed over the columns The glass temperature is then raised to a point where the glass begins to flow. It flows around the columns, and then solidifies and cools. The molten glass takes up the shape of the template substrate upon which it was resting. Upon cooling, the glass may be removed from the template substrate, or the template substrate removed from the glass, whereupon high aspect ratio holes remain in the glass. More generally, one may form a via through the thickness of substrate (a “through substrate via” or TSV) by forming a pattern of lands and spaces on a silicon template substrate, disposing a slab of glass material over the template substrate to form a wafer assembly, and melting the slab of glass material until it flows into the spaces and between the lands.

In one embodiment, the template substrate is silicon, and the columns are formed in this silicon substrate. In another embodiment, the template substrate is glass, and metal vias are deposited in the holes made in the glass wafer. In third embodiment the template substrate is glass and Si posts made from heavily doped Si wafer and are left in the glass to form the vias.

Numerous devices can make use of the systems and methods disclosed herein. In particular, RF switches benefit from the reduced capacitive coupling that an insulative substrate can provide. High density vias formed in the insulative substrate increase the density of devices which can be formed on a substrate, thereby reducing cost to manufacture. The performance of such devices may also be improved, in terms of insertion loss, distortion and isolation figures of merit.

One such device is a capacitive switch, which carries high frequency RF signals to a junction. Another example is a low frequency DC switch which must carry large currents in an insulating substrate. A third example is a photovoltaic cell used for power generation.

These and other features and advantages are described in, or are apparent from, the following detailed description.

### BRIEF DESCRIPTION OF THE DRAWINGS

Various exemplary details are described with reference to the following figures, wherein:

FIG. 1 is a cross sectional view of a template substrate with columns formed thereon;

FIG. 2 is a cross sectional view of the template substrate with a glass wafer positioned overtop of the template substrate;

FIG. 3 is a cross sectional view of the glass wafer heated above its softening temperature, whereupon the glass wafer melts onto the template substrate;

FIG. 4 is a cross sectional view of the glass and template substrates, after chemical mechanical polishing planarizes the surface of the substrate, and the template substrate is removed;

FIG. 5 is a cross sectional view of the glass substrate with through vias, wherein metal is deposited in the through vias and electrical pads are disposed over the vias;

FIG. 6 is a cross sectional view of a first exemplary embodiment of the glass substrate with through vias, especially suited to high frequency applications;

FIG. 7 is cross sectional view of a second exemplary embodiment of the through substrate via, wherein a silicon via with a glass annulus is formed through a silicon substrate wherein the annulus may provide electrical isolation to the silicon substrate;

FIG. 8 is cross sectional view of a third exemplary embodiment of the through substrate via, wherein a large glass area is formed in a silicon substrate to provide electrical isolation to structures within a switch;

FIG. 9 is a cross sectional view of a fourth exemplary embodiment of the through substrate via, wherein a through silicon via is coated with a layer of polysilicon and then filled with glass;

FIG. 10 is a cross sectional view of a fifth exemplary embodiment of the through substrate via, wherein the through glass vias are used in conjunction with a photosensitive surface such as a photocell;

FIG. 11 is a more detailed cross sectional view of the photovoltaic application of the through substrate via;

FIG. 12a is a cross sectional view of a sixth embodiment of the through substrate via, a silicon via is surrounded by a glass annulus;

FIG. 12b is a plan view of the sixth embodiment; and

FIG. 13 is an exemplary method for forming through vias in a glass substrate.

### DETAILED DESCRIPTION

The systems and methods described herein may be particularly applicable to microelectromechanical devices, wherein the vias may be required to be very low loss or when the device is small. MEMS devices are often fabricated on a composite silicon-on-insulator wafer, consisting of a relatively thick (about 675 μm) “handle” layer of silicon overcoated with a thin (about 1 μm) layer of silicon dioxide, and covered with a silicon “device” layer. The MEMS device is made by forming moveable features in the device layer by, for example, deep reactive ion etching (DRIE) with the silicon dioxide layer forming a convenient etch stop. The movable feature is then freed by, for example, wet etching the silicon dioxide layer from beneath the moveable feature. Alternately, MEMS devices can be fabricated on a thin Silicon wafer by depositing and etching thin solid layers of metals and non-metals. If one of these layers is a sacrificial layer, the MEMS device can be released by etching this sacrificial layer, thus freeing the device or feature to move. The moveable features may then be hermetically encapsulated in a cap or lid wafer, which is bonded or otherwise adhered to the top of the silicon device layer, to protect the moveable features from damage from handling and/or to seal a particular gas in the device as a preferred environment for operation of the MEMS device.

Through-hole vias are particularly convenient for MEMS devices, because they may allow electrical access to the encapsulated devices. Without such through holes, electrical access to the MEMS device may have to be gained by electrical leads routed under the capping wafer which is then hermetically sealed. It may be problematic, however, to achieve a hermetic seal over terrain that includes the electrical leads unless more complex and expensive processing steps are employed. This approach also makes radio-frequency applications of the device limited, as electromagnetic coupling will occur from the metallic bondline residing over the normally oriented leads. Alternatively, the electrical access may be achieved with through-wafer vias formed through the handle wafer, using the systems and methods described here.

The systems and methods described herein may be particularly applicable to vacuum encapsulated microelectromechanical (MEMS) devices, such as a MEMS actuator, a sensor, or an infrared microdevice. However, they may also be applicable to any integrated circuit formed on a device wafer and encapsulated with a lid wafer.

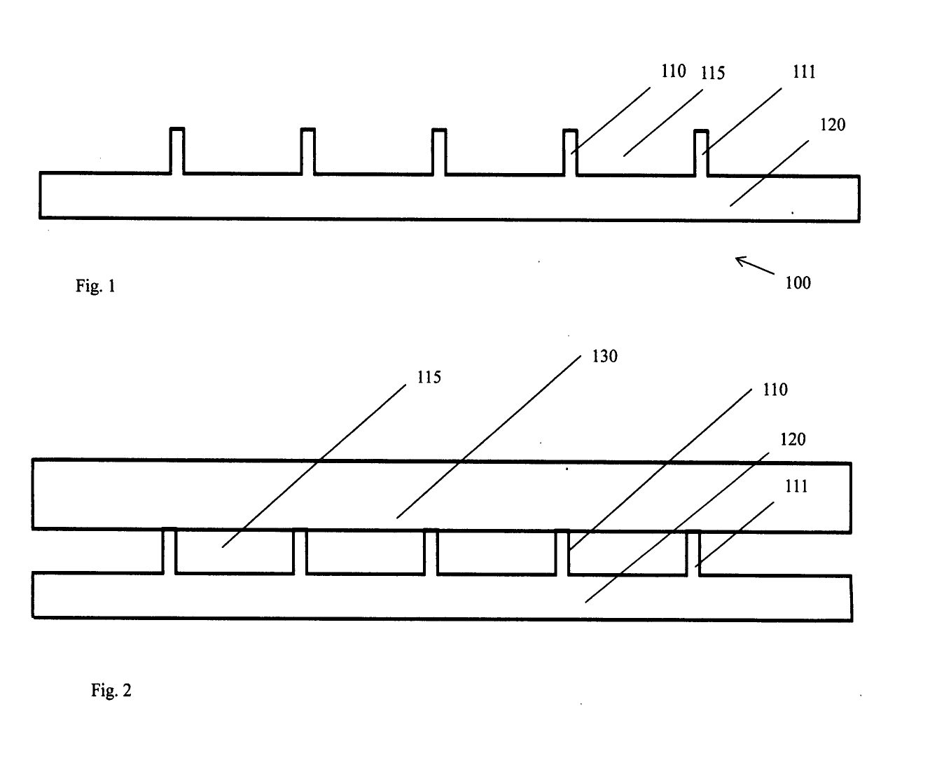

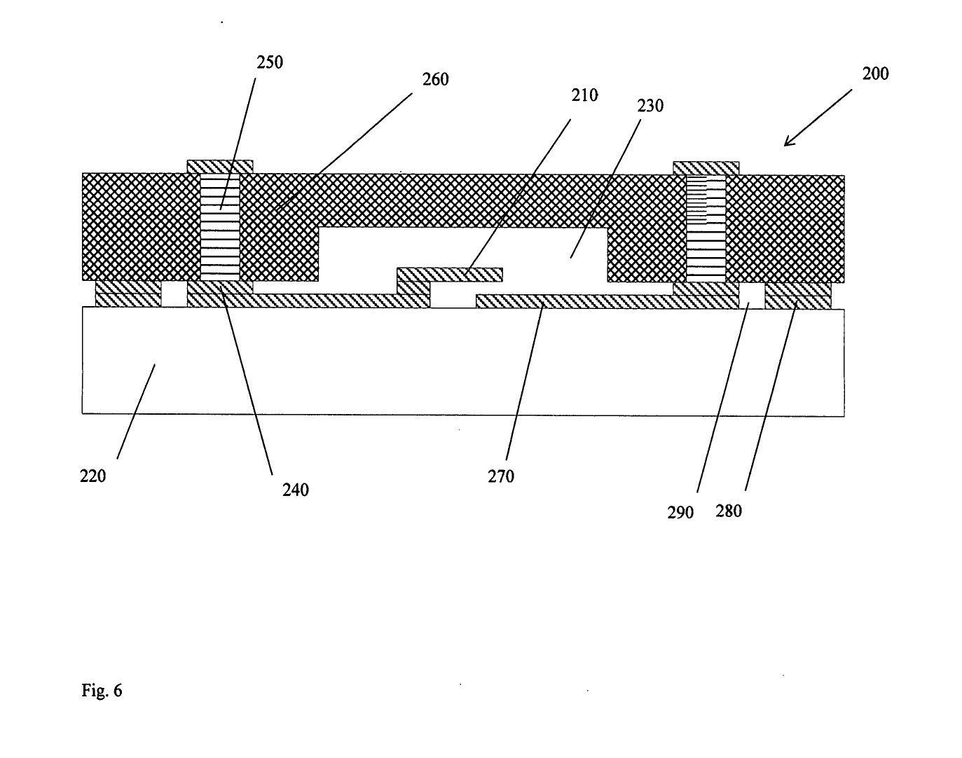

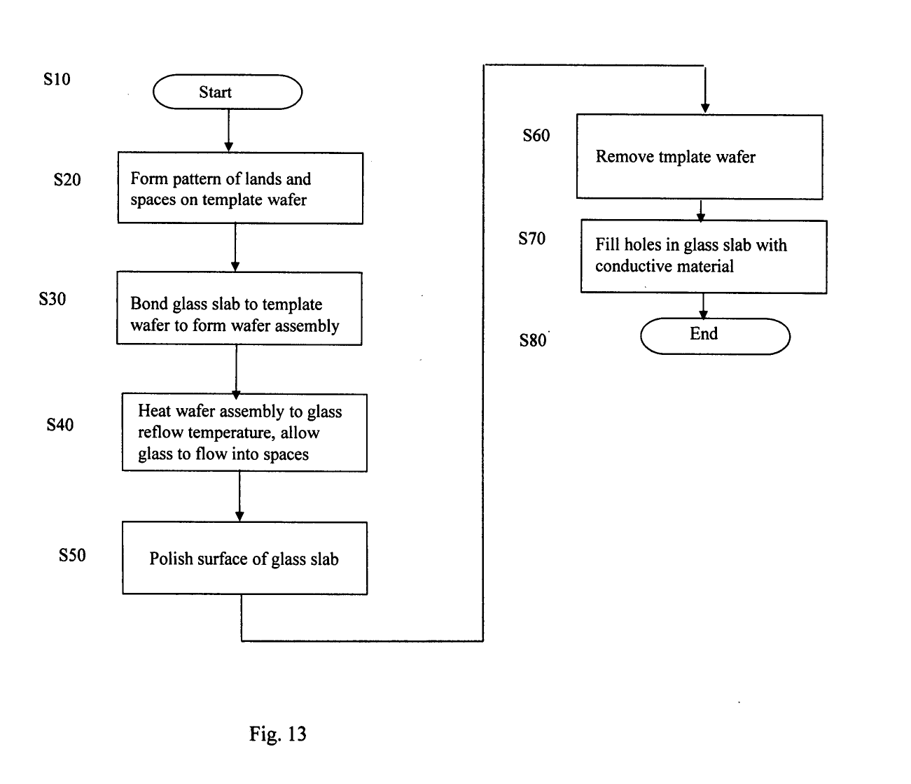

The general method is illustrated in FIGS. 1-5. Exemplary embodiments of devices that may make use of the method are illustrated in FIGS. 6-12b; a flowchart of an exemplary method is given in FIG. 13.

FIG. 1 is a diagram of an exemplary template wafer 100 upon which a plurality of columns 110 may be formed. The columns 110 may be formed with a height sufficient to protrude entirely through the TSV wafer to come. The “TSV” wafer should be understood to mean a wafer which will have the vias formed therein, and which will, with a second wafer, encapsulate the device if a device cavity is to be formed. A substrate 120 may be a standard silicon wafer, initially about 500 um thick. The columns 110 may have about a 20/1 aspect ratio, and may be, for example, about 10 um to about 200 um in diameter, and about 3 um-400 um tall. The thickness of the remaining substrate material of the template substrate may be, for example, about 300 um thick. The columns 110 may be formed using standard photolithographic processes, including the deposition and patterning of photoresist, followed by the etching of the material of the substrate 120 according to the pattern in the photoresist.

Upon forming the template wafer 100, a glass slab or wafer 130 may be placed overtop the columns 110. The glass slab may be, for example, borosilicate or fused silica glass. The slab may be, for example, about 700 um thick. The glass slab 130 may be anodically or fusion bonded to the silicon template substrate, by for example, applying heat and/or voltage between the wafers. Voltages on the order of 1 kV may be required for anodic bonding, and temperatures in the range of about 200-500 C for 5-20 minutes may be required. Anodic and fusion bonding of silicon and glass wafers are well known in the art. The silicon substrate 120 is shown bonded to the glass wafer 130 in FIG. 2.

It should be noted that one of the features 111 shown in FIGS. 1 and 2 may be a raised feature which forms a ring around each device or the whole wafer. The purpose of this raised feature 111 is to form a vacuum cavity 115 in the interior of the space created by the columns 110 and the glass slab 130. This vacuum cavity 115 may assist in the formation of the TSV wafer as described further below.

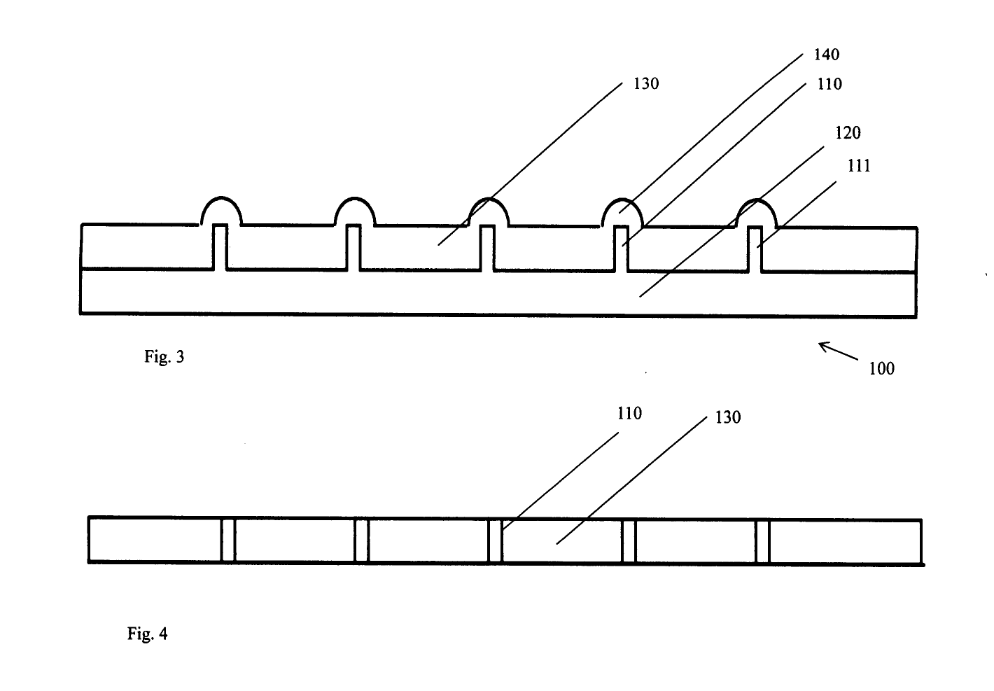

FIG. 3 shows the condition of the silicon substrate 120 and the glass wafer 130 after heating the glass wafer to its softening temperature. Because of the vacuum cavity 115 that exists below the glass wafer 130, the material of the glass wafer 130 tends to descend into the cavity 115 upon melting. For borofloat glass, which is typically used in anodic bonding, this reflow is carried out at a temperature just above the softening point (820 C). This can be done at atmospheric pressure to provide a pressure differential that drives the glass into the internal vacuum.

Because of the finite viscosity of the soft glass, the coating of the template substrate 100 may be somewhat conformal, so that a raised feature 140 exists above each column 110. This excess material may be removed easily by, for example, chemical mechanical polishing CMP. The silicon template substrate 100 may also be removed by polishing or etching, leaving only the glass material 130 with conductive columns 110 formed therein. The condition of the polished substrate assembly is shown in FIG. 4.

The columns 110 may now be vias 110, and are formed in the glass material 130. The columns or vias 110 may therefore consist of the silicon material from the silicon template substrate, and thus may be conducting, depending on the doping level of the silicon. The vias may therefore form a plurality of wires extending through the thickness of the slab of glass material and having a center to center tolerance of less than about 5 microns. As a result of this manufacturing process, the vias may have excellent dimensional and location tolerance, to within the less than the 5 micron tolerance just mentioned. If preferred, however, this silicon may be removed and replaced with, for example, copper or gold. These materials may have superior electrical properties to silicon, which may be required for some applications. Alternatively, the silicon may be removed to leave a glass slab with a plurality of substantially vertical channels formed therein.

“Substantially vertical”and “substantially perpendicular” may be understood to mean parallel to within about 5 degrees, with respect to adjacent channels, and perpendicular within about 5 degrees to top surface, respectively. The glass slab 130 thereby has an array of precisely shaped pillars and may form a micro-lens array after the Si wafer is removed which are substantially parallel to one another. Such microlens arrays may be useful in, for example, photomultiplier tubes, wherein the vertical channels direct short wavelength photons onto a pixelated detector.

To form the through substrate vias with copper (Cu) via rather than silicon, the following process may be undertaken: After removal of the silicon by, for example, chemical etching,

(1) deposition of a seed layer to permit electrochemical deposition (ECD) into the hole,

(2) electrochemical deposition (ECD) of the Cu,

(3) planarization,

(4) seed layer removal,

(5) trace metal processing,

(6) backside grind and chemical mechanical polishing (CMP) to expose the buried Cu

(7) backside trace metal processing.

In the process outlined above, the seed layer may be, for example, a thin layer of gold or copper deposited conformally to a thickness of less than about 1 um.

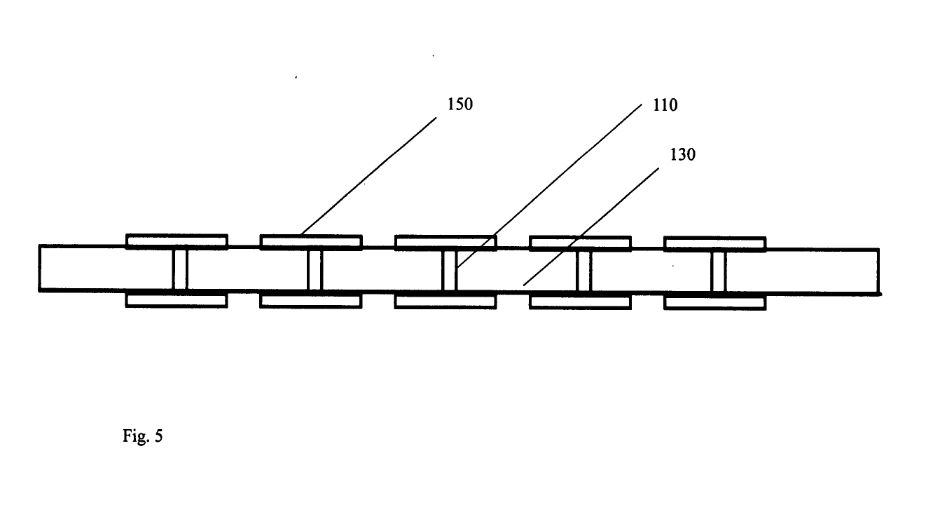

To provide a location for solder or bump bonding to the columns or vias 110, metallic pads 150 may be deposited over the columns or vias 110. Such metallization steps are known and are described in, for example, U.S. Pat. No. 7,528,691, U.S. Pat. No. 7,893,798 B2, and U.S. Pat. No. 7,569,926, each of which is incorporated by reference in its entirely, and is assigned to the assignee of the present application. Details of other processing steps may also be found in these incorporated applications. The condition of the completed structure, henceforth referred to as the “through substrate via” (TSV) is shown in FIG. 5.

Exemplary dimensions of the device shown in FIG. 5 are: aspect ratio (depth to diameter) of column or via 110 about 20 to 1, width of via may be about 10 um to about 200 um, depth of via may be about 3 um to about 400 um. The through substrate via wafer may be glass of thickness up to about 400 um, or may be, fused silica, borosilicate glass (such as borofloat®), pyrex®, etc. The through substrate via may be non-conductive. The through substrate conductive vias may be silicon, gold, copper or nickel, for example.

It should be understood that other designs of template substrates may also be used to practice this invention. FIG. 5 shows the exemplary template silicon substrate wherein the glass “lands” (glass substrate, 130) are larger than the silicon “spaces” (silicon vias, 110). However, it should be understood that the glass “lands” may be made small compared to the silicon “spaces”. This design results in a set of columnar glass features embedded in a silicon substrate. These insulating columns may be useful in certain applications, such as those described below.

FIG. 6 is a cross sectional diagram of one embodiment of the TSV wafer 200. In this embodiment, a cantilevered beam 210 is formed on a conductive substrate 220. The beam is enclosed in a hermetically sealed device cavity 230. If the cantilever is actuated electrostatically, it is desirable to place an electrostatic plate beneath the cantilever, such that a voltage can be applied between the cantilever and the place, which will give rise to electrostatic forces which bend the cantilever toward the plate. In addition, signals or power may be routed to the cantilever 210. Each of these structures requires an electrical connection to be available.

The electrical connections may be provided by a TSV wafer, shown as structure 200 in FIG. 6. The material of the TSV wafer may be a transparent, optical material such as glass. The TSV wafer 200 may be fabricated using the process described above, resulting in a plurality of silicon vias 250 formed in the material 240 of the glass substrate 200. The vias may be capped by a layer of metallization 260 that may be, for example, gold or copper. This layer of metallization 260 may provide electrical connectivity between the via 250 and the cantilever 210 or lower electrode 270. A void 280 may provide electrical isolation between the cantilever 210 and the next adjacent device.

The device shown in FIG. 6 may be especially suitable for small, movable devices such as a low frequency, electrostatic accelerometer or an electrostatic actuator. The deflection of a proof mass by an acceleration may be measured as a change in capacitance between the cantilever 210 and the lower electrode 270. Alternatively, the deflection may be detected by a beam of light reflected by the back surface of the electrode through the transparent TSV wafer. In other applications, the cantilever 210 forms an electrical switch, and the silicon vias 250 are replaced by copper or gold metal vias for high frequency applications. By routing the signals vertically away from the device, capacitive coupling to the leads may be minimized, thus improving switch performance. DC power may also be switched by this device, which may have good thermal properties and thus be able to dissipate the large amounts of heat.

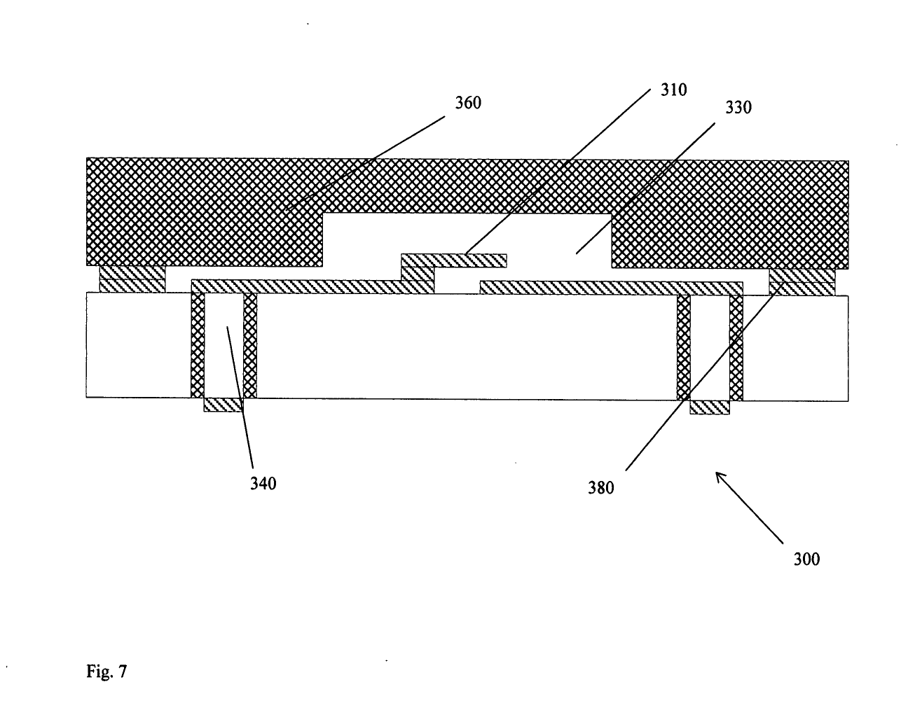

FIG. 7 is a cross sectional diagram of another embodiment of the TSV wafer. The device shown in FIG. 7 may include a cantilever 310 similar to cantilever 210 in FIG. 7, but the cantilever 310 may be suspended over a silicon substrate 300. As before, the capping wafer 360 may be a transparent, glass wafer allowing light transmission and low capacitive coupling. In the supporting device substrate 300, which may be silicon, for example, there may be through substrate vias (TSVs) 340. The material filling the via 340 may be reflowed glass, using the process described above. This embodiment may be appropriate for resonant beam sensors, wherein the mechanical resonant frequency of the beam is shifted by a change in mass. Often optical sensing is used to monitor the frequency and thus the mass. Glass filled vias can provide a path for optical access. The capping wafer 360 and silicon substrate 300 wafer may form a device cavity 330 therebetween, which may encloses the cantilever in a vacuum.

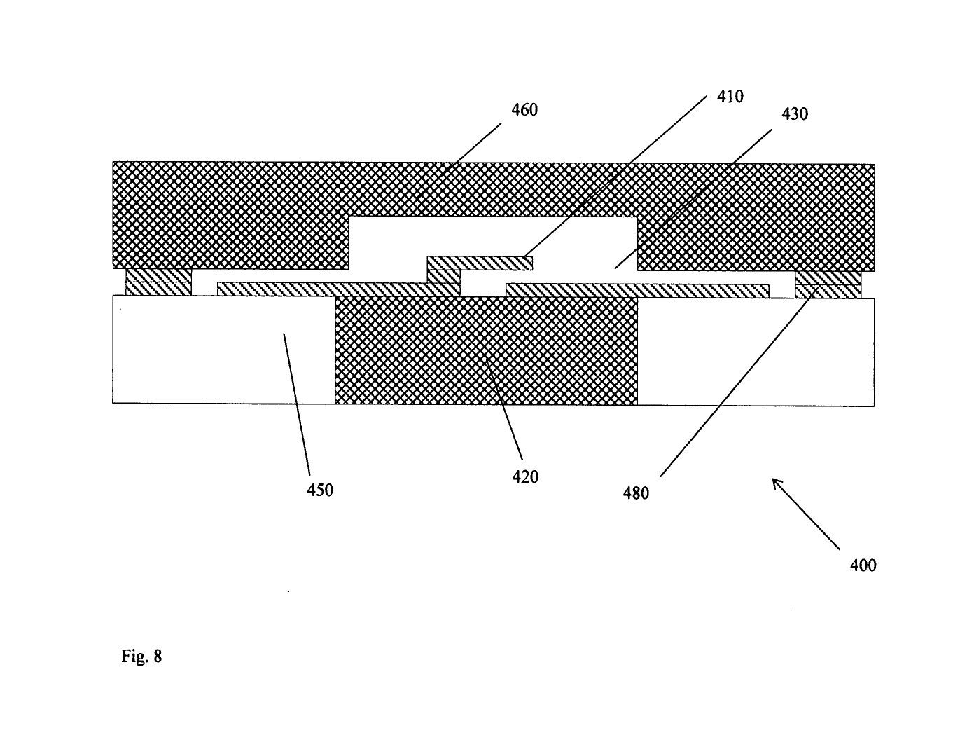

FIG. 8 is a cross sectional diagram of another embodiment of the TSV wafer. The device shown in FIG. 8 may include a cantilever 410 similar to cantilever 210 in FIG. 7, but the cantilever 410 may be suspended over a glassy area 420 inlaid in a silicon substrate 400. As before, the capping wafer 460 may be a transparent, glass wafer allowing light transmission and low capacitive coupling, or it may be a usual silicon substrate. The glassy area 420 may be formed using the process described above with respect to FIGS. 1-6, and especially FIG. 6. The large glassy underfill area 420 may provide better isolation to selected device areas while having additional CMOS devices (not shown) in neighboring silicon areas. Again, an evacuated cavity 430 may enclose the device.

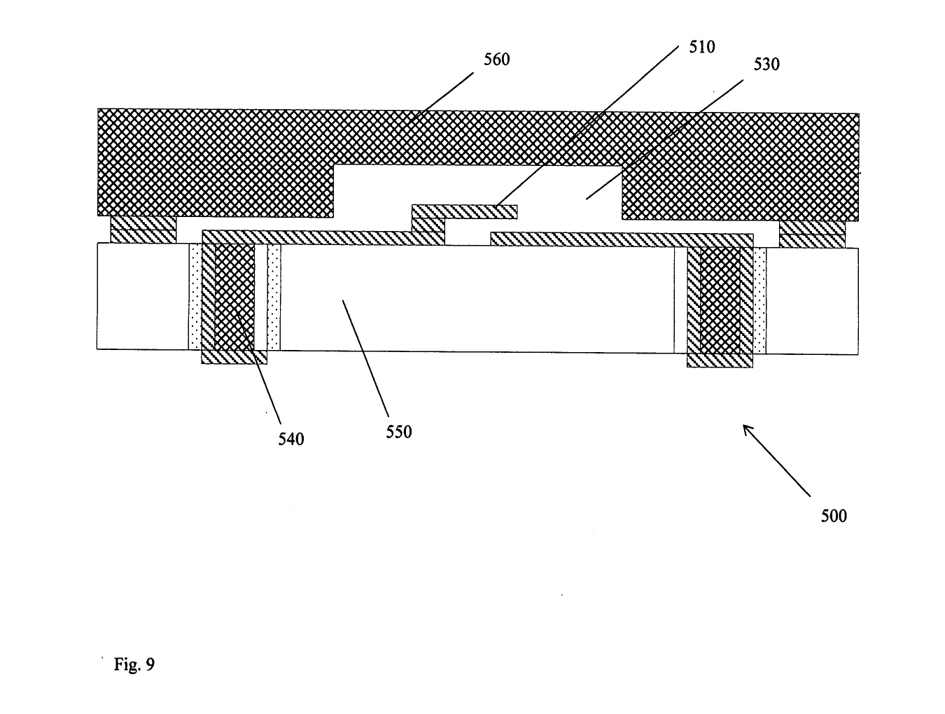

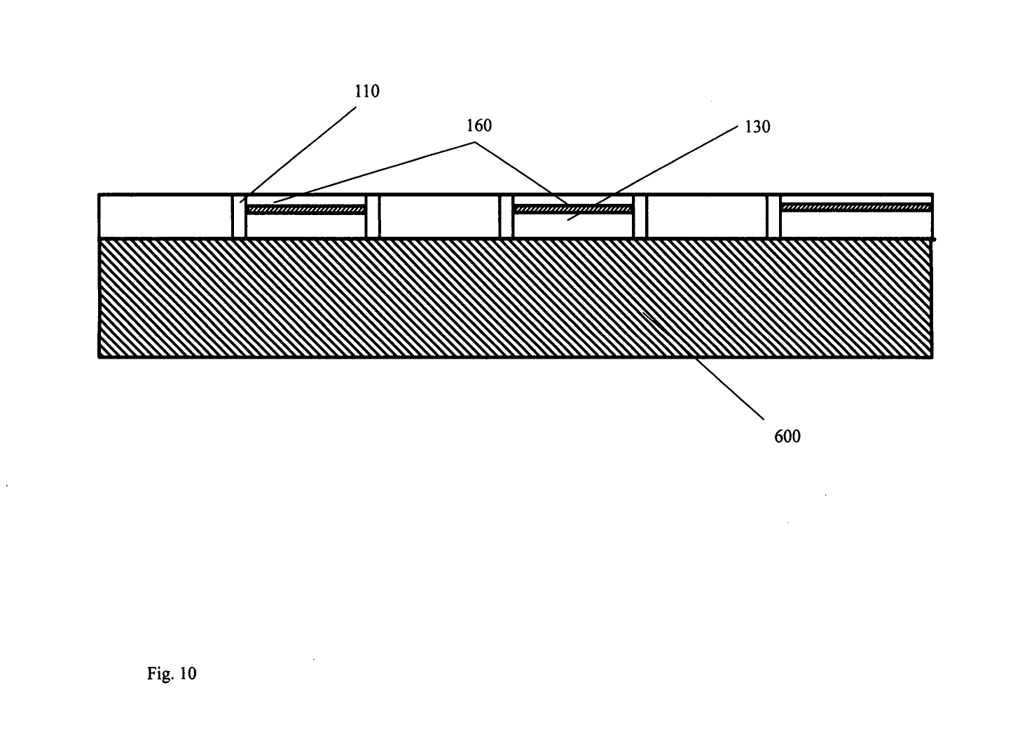

FIG. 9 is a cross sectional diagram of another embodiment of the TSV wafer. The device shown in FIG. 9 may include a cantilever 510 similar to cantilever 210 in FIG. 7, but the cantilever 510 may be suspended over a glass substrate 550. As before, the capping wafer 560 may be a transparent, glass wafer allowing light transmission and low capacitive coupling, or it may be a usual silicon substrate. In contrast to FIG. 8, there may be no dielectric layer under cantilever 510, but instead the whole wafer may be dielectric glass or ceramic 550. Conductive vias 540 may be formed in the glass using the process described above, which may be used to provide the signals or voltages required to control the device 510. The large dielectric area 550 beneath the device may reduce capacitive coupling, thus resulting in better high frequency performance relative to the embodiment shown in FIG. 8. Again, an evacuated cavity 530 may enclose the device.

FIG. 10 is a schematic cross sectional view of another embodiment of the TSV structure, in which the glass slab 130 is of a material that has a similar or substantially the same coefficient of thermal expansion (CTE) to that of silicon. Borofloat glass®, pyrex®, both borosilicate glasses, and fused silica are examples of suitable materials whose CTE is acceptably close to that of silicon. Borofloat glass, manufactured by Schott AG, is a highly chemically resistant borosilicate glass with low thermal expansion that is produced using the float method, and having a composition of 81% SiO,: 13$ B₂O₃; 4% Na₂O/K₂O; and 2% Al₂O,. Pyrex, developed by Corning, contains 80.6% SiO₂, 12.6% B₂O₃, 4.2% Na₂O, 2.2% Al₂O₃, 0.04% Fe₂O₃, 0.1% CaO, 0.05% MgO, and 0.1% Cl. However, it should be understood that a material having a CTE substantially the same as silicon should be understood to mean any material whose CTE is within about +/−1 ppm/C of that of silicon. It should be understood that this selection of materials may be applied to all the previously described embodiments shown in FIGS. 1-9. As a result of this selection of materials, the glass portion will not fracture or shatter away from the silicon as the structure is heated. For this reason, the structures shown in FIGS. 5-11 may be particularly suited to high temperature or variable temperature applications such as photovoltaic panels or refrigeration units. FIG. 10 shows one such example.

In FIG. 10, a large area is patterned and etched to create a large number of substantially vertical silicon posts 110 embedded in the CTE matched glass layer 130.

In one application, a plurality of microfluidic channels 160 may be fabricated in the glass slab 130. These channels may conduct a fluid between the posts, or allow for the expansion or contraction of a gas contained in the channels. These fluidic channels formed in the glass between the Si islands may provide a “thermal short circuit,” that is, areas of high thermal conductivity between the posts. In this architecture, the device 600 may form a section of Joule Thompson Refrigerator that can reach temperatures as low as 77K without fracture of the structure.

In another application, the silicon posts may be appropriately doped either p-type or n-type or both. In this architecture, their surfaces may form the p-n junctions required for photovoltaic (PV) electricity generation. The glassy regions between the posts may serve to focus the radiant energy onto the posts, to increase the light collection efficiency or energy conversion efficiency to electricity from sunlight. The glass 130 may also provide structural strength and rigidity to the unit, important in protecting the thin, fragile silicon material. Importantly, the geometry of this architecture greatly increases the surface area of the p-n junctions. As is well known, having p-n junction with substantial surface area is key to forming highly efficient photovoltaic cells.

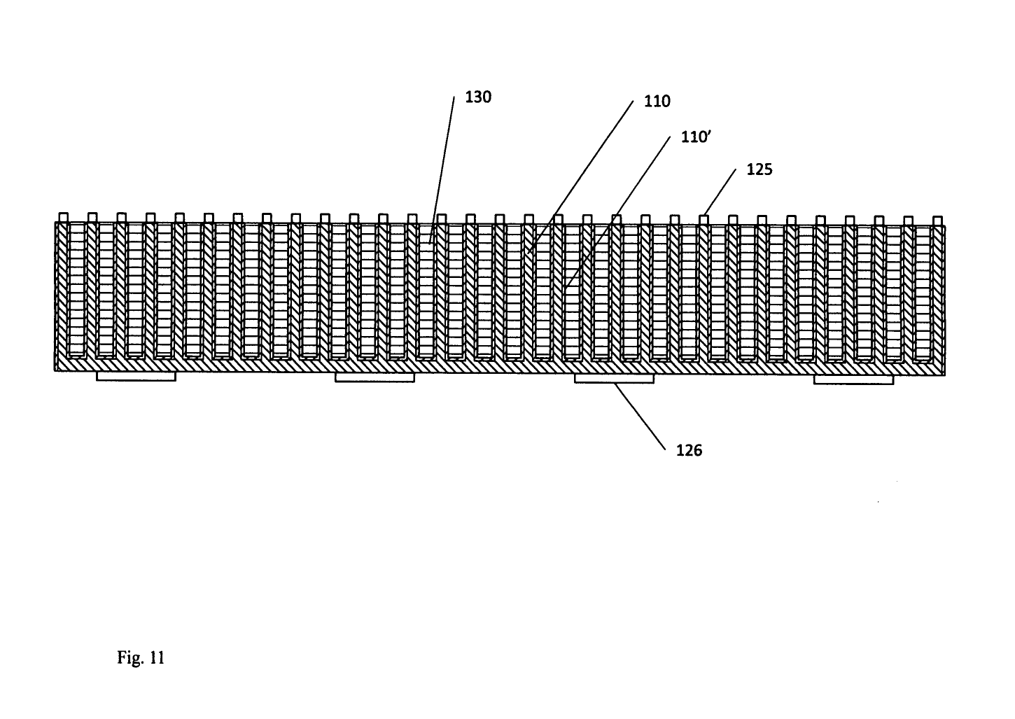

A more detailed view of this photovoltaic application is shown in FIG. 11. As before, reference number 130 corresponds to the glass material which may be formed based on the method described above. As before, a large number of silicon posts 110 protrude into the glass and is covered by another layer of silicon 110′. These posts may be substantially parallel to one another, or parallel to within an angle of less than about 5 degrees. One portion of the silicon may be p-doped, and the other layer 110′ may be n-doped, forming a silicon pn junction, the basis of the photovoltaic effect. Contact 125 may be formed over the post 110 and contact 126 may be formed below the posts 126 to collect the energy. Exemplary thicknesses for the p-layer and n-layer may be, for example, 0.5-5 um. This approach to producing photovoltaic devices may provide very large surface areas for energy generation, thus increasing the energy conversion efficiency while reducing the size and cost of the panel. The device may allow concentrated solar energy to reach the pn junction, reaching high efficiencies and high temperatures without shattering or degrading. For this application, the glass slab 130 may have a surface area of at least about 10 cm×10 cm.

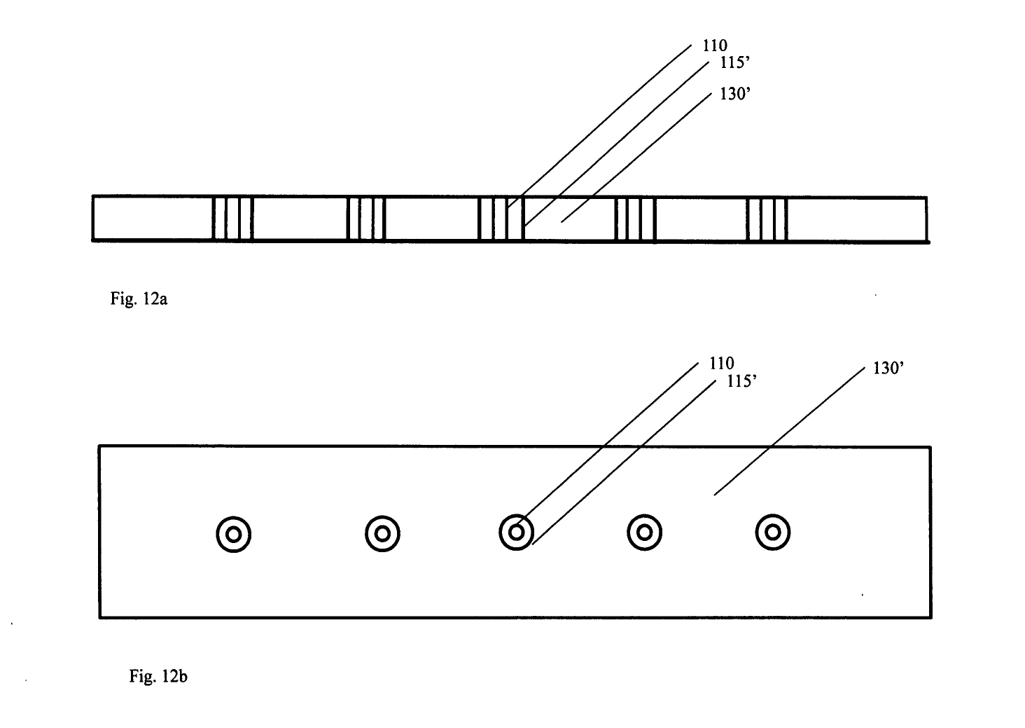

FIG. 12a shows another exemplary embodiment of a device similar to that illustrated in FIG. 11. In this embodiment, layer 130′ may correspond to silicon material rather than glassy material. Within the silicon material 130′, a plurality of glass annuluses 115′ are formed by the reflow process described above, surrounding a plurality of silicon posts 110. The annulus 115′ forms an isolating ring for a Si via 110 in a Si wafer 130′. This isolating ring may be useful for microscopic electrostatic pick and place tips, which must have a front face free of interference. The silicon vias with glass annulus is shown in cross section in FIG. 12a and plan view in FIG. 12b.

FIG. 13 is a flow chart illustrating one method of forming through substrate vias in a glass slab or wafer. The process begins in step S10. In step S20, a pattern of lands and spaces is formed on a template wafer, wherein the dimensions of the features correspond to the eventual vias to be formed in the glass slab or wafer. In step S30, a glass slab or wafer is bonded to the template wafer, and the bonding chamber is evacuated. In step S40, the wafer assembly is heated to the glass reflow temperature. In step S50, the surface of the glass slab may be polished. In step S60, the template wafer is removed, leaving holes or vias through the thickness of the glass slab or wafer. In step S70, the holes in the glass slab or wafer are filled with a filler material, if needed. In one exemplary embodiment, the filler material is gold or copper, which is electroplated onto a seed layer disposed in the hole.

It should be understood that this process is exemplary only, and that steps can be added or omitted, or performed in a different order than that shown without deviating from the scope of this invention. For example, if the template wafer is removed by grinding, leaving silicon columns in the via holes formed in the glass slab or wafer, the vias may already be sufficiently conductive, and step S70 may not be necessary. It should also be understood that as described above, the holes in the glass slab may be filled with any number of filler materials, including conductive materials such as copper.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure.

1. A method for forming a through substrate via, comprising:
forming a pattern of lands and spaces on a silicon template substrate;
disposing a slab of glass material over the template substrate to form a wafer assembly; and
melting the slab of glass material until it flows into the spaces and between the lands,
wherein the slab of glass material has a coefficient of thermal expansion which is substantially the same as silicon, and further comprising a plurality of fluidic channels formed in the glass and configured to provide a thermal short between the lands in the silicon template substrate.

2. The method of claim 1, further comprising:
removing at least a portion of the template wafer to leave the slab of glass with at least one hole formed therein corresponding to a location of the lands formed on the template substrate, and extending through a thickness of the glass slab.

3. The method of claim 1, further comprising:
removing at least a portion of the slab of glass to leave the template substrate with glass material disposed in the hole, and extending through a thickness of the template substrate.

4. The method of claim 2, wherein the at least one hole is filled with a conductive material, to form a via extending through the thickness of the glass slab, wherein the vias form a plurality of wires extending through the thickness of the slab of glass material.

5. The method of claim 1, wherein disposing the slab of glass material over the template substrate comprises anodically bonding the glass slab to the template substrate with a combination of heat and voltage.

6. The method of claim 4, wherein the conductive material comprises at least one of silicon, copper and gold.

7. The method of claim 1, wherein the glass material comprises at least one of a borosilicate glass and fused silica.

8. The method of claim 1, further comprising:
evacuating a bonding chamber containing the template substrate and the slab of glass material;
forming a vacuum in the spaces of the template substrate, between the template substrate and the slab of glass material.

9. The method of claim 2, further comprising:
depositing a seed layer into the at least one hole; and
electroplating at least one of copper, nickel and gold onto the seed layer to fill the hole with conductive material.

10. The method of claim 1, further comprising:
applying a voltage between the slab of glass material and the template substrate; and
heating the wafer assembly.

11. The method of claim 4, wherein bonding the template substrate to the slab of glass material comprises:
aligning the template substrate to the slab of glass material;
applying pressure between the template substrate and the slab of glass material; and
applying heat to the template substrate and the slab of glass material.

12. The method of claim 1, wherein the lands and spaces comprise a plurality of columns between about 50 um and 200 um wide, and between about 3 um and 400 um tall, and separated by at least about 500 um.

13. The method of claim 3, further comprising:
bonding the slab of glass material with the at least one hole filled with a conductive material, to form a via extending through the thickness of the slab of glass material to a device wafer including an electrical device enclosed in a device cavity, such that the via provides electrical access to an electrical feature inside the device cavity.

14. The method of claim 1, wherein the slab of glass material has a coefficient of thermal expansion that is substantially the same as the coefficient of thermal expansion of the silicon template substrate.

15. The method of claim 1, further comprising: bonding the slab of glass material to a Si wafer that is patterned and etched to create very large surface area having a large number of substantially parallel holes or trenches formed therein.

16. The method of claim 1, further comprising: bonding the slab of glass material to Si wafer that has an array of substantially vertical pillars or fins formed therein;
reflowing the glass to fill the spaces between the pillars or fins, to form a microlens array in the glass slab upon removal from the template substrate.

17. The method of claim 15, wherein the slab of glass material has a surface area of at least about 10 cm, and is configured as a photovoltaic panel.

18. (canceled)

20. The method of claim 1, wherein the slab of glass material is reflowed into an annulus space around at least one silicon post formed in the silicon template substrate, such that at least one glass annulus is formed around at least one silicon post.

21. A through via substrate made by the method of claim 1, comprising:
a glass substrate having a plurality of conductive wires extending through the thickness of the glass subtrate.
